(19) United States
(12) Patent Application Publication
(10) Pub. No.: US 2022/0100409 A1
(43) Pub. Date: Mar. 31, 2022

(54) MEMORY AND METHOD FOR TESTING MEMORY

(71) Applicant: CHANGXIN MEMORY TECHNOLOGIES, INC., Hefei City (CN)

(72) Inventors: Jia Wang, Hefei (CN); Yuanyuan Sun, Hefei (CN)

(21) Appl. No.: 17/409,987

(22) Filed: Aug. 24, 2021

Related U.S. Application Data
(63) Continuation of application No. PCT/CN2021/099988, filed on Jun. 15, 2021.

(30) Foreign Application Priority Data
Sep. 30, 2020 (CN) 202011058602.4

(51) Int. Cl. G06F 3/06

(52) U.S. Cl. CPC G06F 3/0653; G06F 3/0673; G06F 3/0608; G06F 3/0655

(57) ABSTRACT

Memory and a method for testing memory, the memory includes a storage module, a read-write drive module, and a data processing module. The storage module is configured to store data information and includes main storage modules and a parity bit storage module, the main storage module being configured to store valid data and the parity bit storage module being configured to store parity bit data. The read-write drive module is connected to the storage module, and configured to read the data information from the storage module or write the data information into the storage module. The data processing module is connected to the read-write drive module and configured to perform a decoding operation of error checking and correcting on the data information output from the read-write drive module, or configured to perform an encoding operation of error checking and correcting on data information input into the read-write drive module.

### CROSS-REFERENCE TO RELATED APPLICATIONS

This is a continuation of International Application No. PCT/CN2021/099988, filed on Jun. 15, 2021, which claims priority to Chinese Patent Application No. 202011058602.4, filed on Sep. 30, 2020. The contents of International Application No. PCT/CN2021/099988 and Chinese Patent Application No. 202011058602.4 are incorporated herein by reference in their entireties.

### TECHNICAL FIELD

The present disclosure relates to the field of semiconductors, and more particularly, to a memory and a method for testing a memory.

### BACKGROUND

In the current application of memory, it is able to detect and correct a one-bit error occurred from stored data of the memory by introducing Error Checking and Correcting (ECC).

The memory that introduces ECC requires an additional storage region in the storage region to store ECC parity bit data. Therefore, when testing the storage region of the memory, the storage region that stores ECC parity bit data also needs to be tested to prevent errors also occurred in the storage region that stores ECC parity bit data during the memory manufacturing process.

However, in the related art, a test for the storage region which is configured to store valid data (that is, data input from the outside of the memory) in the memory is separate from a test for the storage region which is configured to store ECC parity bit data, that is, the storage region for valid data and the storage region for ECC parity bit data are tested separately. The existing test process is complicated and has low efficiency.

### SUMMARY

In a first aspect, an embodiment of the present disclosure provides a memory, including: a storage module, configured to store data information, herein the storage module includes main storage modules and a parity bit storage module, the main storage module is configured to store valid data, and the parity bit storage module is configured to store parity bit data; a read-write drive module, connected to the storage module and configured to read the data information from the storage module, or write the data information into the storage module; and a data processing module, connected to the read-write drive module and configured to perform a decoding operation of error checking and correcting on the data information output from the read-write drive module, or perform an encoding operation of error checking and correcting on the data information input into the read-write drive module.

In a second aspect, an embodiment of the present disclosure provides a method for testing a memory, which is applied to the above-mentioned memory and includes: outputting test data into the memory based on the data pad; writing the test data into the main storage module and the parity bit storage module; reading the test data stored in the main storage module and the parity bit storage module through the compression read module and outputting the compressed data; and determining whether the storage module is in a normal operating state based on the compressed data.

In a third aspect, an embodiment of the present disclosure provides a method for testing a memory, which is applied to the above-mentioned memory and includes: storing the test data into the test case register; writing the test data output from the test case register into the main storage module and the parity bit storage module; reading the test data stored in the main storage module and the parity bit storage module through the compression read module and outputting the compressed data; and determining whether the storage module is in a normal operating state based on the compressed data.

### BRIEF DESCRIPTION OF THE DRAWINGS

One or more embodiments are illustrated by the pictures in the corresponding drawings. Unless otherwise stated, the pictures in the drawings do not limit the scale.

FIG. 1 and FIG. 2 are schematic structural diagrams of a memory provided by a first embodiment of the present disclosure.

FIG. 3 and FIG. 4 are schematic structural diagrams of a memory provided by a second embodiment of the present disclosure.

FIG. 5 and FIG. 6 are flowcharts of a method for testing a memory provided by a third embodiment of the present disclosure.

### DETAILED DESCRIPTION

In the current application of memory, it is able to check and correct a one-bit error occurred from stored data of the memory by introducing Error Checking and Correcting (ECC).

The memory that introduces ECC requires an additional storage region in the storage region to store ECC parity bit data. Therefore, when the storage region of the memory is tested, the storage region that stores the ECC parity bit data also needs to be tested to prevent errors also occurred in the storage region for storing the ECC parity bit data during the memory manufacturing process.

However, the test flows for testing the storage region of the valid data and the storage region of the ECC parity bit data in the memory is complex and has low testing efficiency.

In order to solve the above-mentioned problem, the first embodiment of the present disclosure provides a memory which includes a storage module, a read-write drive module, and a data processing module. The storage module is configured to store data information and includes main storage modules and a parity bit storage module, the main storage module being configured to store valid data and the parity bit storage module being configured to store parity bit data. The read-write drive module is connected to the storage module, and configured to read the data information from the storage module or write the data information into the storage module. The data processing module is connected to the read-write drive module and configured to perform a decoding operation of error checking and correcting on the data information output from the read-write drive module, or configured to perform an encoding operation of error checking and correcting on the data information input into the read-write drive module.

In order to make the objectives, technical solutions, and advantages of the embodiments of the present disclosure clearer, each embodiment of the present disclosure will be described below in detail in combination with the drawings. However, those of ordinary skill in the art can understand that, in each embodiment of the present disclosure, many technical details are proposed to make readers understand the present disclosure better. However, the technical solutions claimed by the present disclosure may also be implemented even without these technical details and various variations and modifications made based on each of the following embodiments. Division of each of the following embodiments is for ease of description and should not form any limit to specific implementation modes of the present disclosure. Each embodiment can be combined and refer to each other without conflicts.

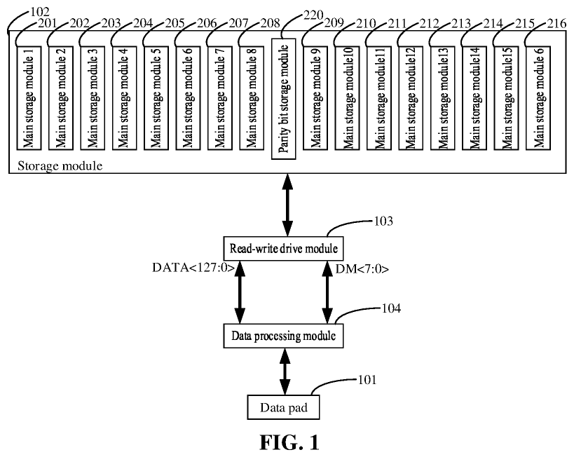

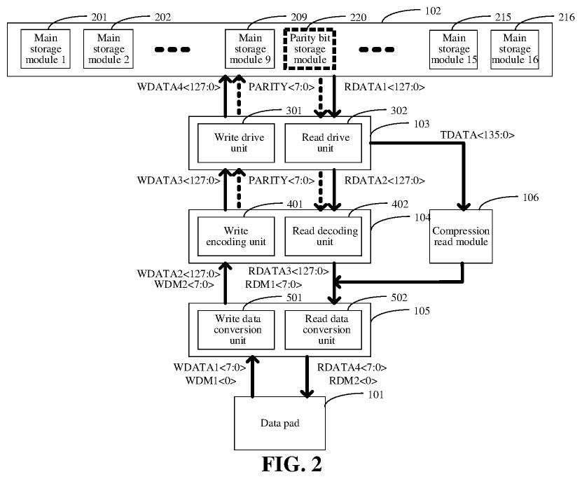

FIG. 1 and FIG. 2 are schematic structural diagrams of a memory provided by the embodiment of the present disclosure. The memory of this embodiment will be described in detail below. It is to be noted that the description of binary bits of each stored data in this embodiment is intended to make the technical means of this embodiment clear to those skilled in the art, and the present disclosure is not limited to this.

Referring to FIG. 1 and FIG. 2, a memory includes a storage module 102.

The storage module 102 is configured to store data information. The data information includes valid data and parity bit data. The valid data is externally input data that needs to be stored in the storage module 102 and the parity bit data is data obtained by ECC checking on the valid data.

Specifically, the storage module 102 includes main storage modules and a parity bit storage module 220. The main storage module is configured to store the valid data and the parity bit storage module 220 is configured to store the parity bit data.

In the embodiment, the main storage modules includes a main storage module 1 (201), a main storage module 2 (202), a main storage module 3 (203), a main storage module 4 (204), a main storage module 5 (205), . . . , a main storage module 15 (215), and a main storage module 16 (216). It is to be noted that 16 main storage modules are taken as an example in the embodiment to introduce the storage module 102 in detail. The purpose is to make the technical means of this embodiment clear to those skilled in the art, and the present disclosure is not limited to this.

In this embodiment, the memory also includes a data pad 101 and a read-write data conversion module 105. Specifically, the read-write data conversion module 105 includes a write data conversion unit 501 and a read data conversion unit 502.

The data pad 101 is configured to exchange, with an external controller, a first write valid data WDATA1<127:0>, a first write mask data WDM1<7:0> corresponding to the first write valid data WDATA1<127:0> and transmitted through a mask data bus, a fourth read valid data RDATA4<127:0>, and a second read mask data RDM2<7:0> corresponding the fourth read valid data RDATA4<127:0> and transmitted through the mask data bus.

The WDATA1<127:0> indicates that the first write valid data is a 128-bit binary number, and according to the result, the WDM1<7:0> indicates whether the first write valid data is valid. In one example, when a bit in the WDM1<7:0> is 0, it indicates that the corresponding 8-bit binary number in the WDATA1<127:0> is invalid.

The RDATA4<127:0> indicates that the fourth read valid data is a 128-bit binary number, and according to the result, the RDM2<7:0> indicates whether the fourth read valid data is valid. In one example, when a bit in the RDM2<7:0> is 0, it indicates that the corresponding 8-bit binary number in the RDATA4<127:0> is invalid.

Specifically, the data pad 101 is configured to obtain the external first write valid data WDATA1<127:0> to be stored, and output the fourth read valid data RDATA4<127:0> stored in the memory to the outside.

The write data conversion unit 501 is connected to both the data pad 101 and a data processing module 104 to perform serial-to-parallel conversion on the first write valid data WDATA1<127:0> and output a second write valid data WDATA2<127:0> to the data processing module 104. The second write valid data WDATA2<127:0> is 16 8-bit binary numbers in parallel. Specifically, the write data conversion unit 501 is configured to convert the serial first write valid data WDATA1<127:0> into a plurality of parallel second write valid data WDATA2<127:0> to improve the efficiency of subsequently storing the data information into the storage module 102.

It is to be noted that the write data conversion unit 501 is also configured to perform serial-to-parallel conversion on the first write valid data WDATA1<127:0> and output a second write mask data WDM2<7:0> to the data processing module 104. The second write mask data WDM2<7:0> is 8 1-bit binary numbers in parallel.

The read data conversion unit 502 is connected to both the data pad 101 and the data processing module 104 to perform parallel-to-serial conversion on a third read valid data RDATA3<127:0> output from the data processing module 104 and output the fourth read valid data RDATA4<127:0> to the data pad 101. The third read valid data RDATA3<127:0> is 16 8-bit binary numbers in parallel.

Specifically, the read data conversion unit 502 is configured to convert a plurality of third read valid data RDATA3<127:0> in parallel to a fourth read valid data RDATA4<127:0> in serial for the memory to output a complete stored data, thereby avoiding loss of the output data.

It is to be noted that the read data conversion unit 502 is also configured to perform parallel-to-serial conversion on the first read mask data RDM1<7:0> and output a second read mask data RDM2<7:0> to the data processing module 104. The second read mask data RDM2<7:0> is 1 serial 8-bit binary number.

The data processing module 104 is connected to the read-write drive module 103 to perform the decoding operation of error checking and correcting on the data information output from the read-write drive module 103, or perform the encoding operation of error checking and correcting on the data information input into the read-write drive module 103.

In this embodiment, the data processing module 104 includes a write encoding unit 401 and a read decoding unit 402.

The write encoding unit 401 is connected to both the read-write drive module 103 and the write data conversion unit 501 to perform the encoding operation of error checking and correcting on the second write valid data WDATA2<127:0> and outputs a third write valid data WDATA3<127:0> and a first write parity bit data WPARITY1<7:0>. The third write valid data WDATA3<127:0> is 16 8-bit binary numbers in parallel and the first write parity bit data WPARITY1<7:0> is 1 8-bit binary number.

Specifically, the write encoding unit 401 is configured to perform the ECC checking on the second write valid data WDATA2<127:0> received to obtain the first write parity bit data WPARITY1<7:0> of the second write valid data WDATA2<127:0>. The second write valid data WDATA2<127:0>, after the ECC checking, is changed to the third write valid data WDATA3<127:0>, which is transmitted, together with the first write parity bit data WPARITY1<7:0>, to the read-write drive module 103.

The read decoding unit 402 is connected to both the read-write drive module 103 and the read data conversion unit 502 to perform the decoding operation of error checking and correcting on a second read valid data RDATA2<127:0> and a second read parity bit data RPARITY2<7:0> output from the read-write drive module 103. The read decoding unit 402 outputs the third read valid data RDATA3<127:0>.

Specifically, the read decoding unit 402 is configured to perform ECC checking and decoding on the second read valid data RDATA2<127:0> according to the second read parity bit data RPARITY2<7:0> to obtain the corresponding third read valid data RDATA3<127:0> decoded by the second read parity bit data RPARITY2<7:0> and transmit the third read valid data RDATA3<127:0> to the read data conversion unit 502. The second read valid data RDATA2<127:0> is 16 8-bit binary numbers in parallel, and the second read parity bit data RPARITY2<7:0> is 1 8-bit parity number.

The read-write drive module 103 is connected to the storage module 102 to read the data information from the storage module 102, or to write the data information into the storage module 102.

In this embodiment, the read-write drive module 103 includes a read drive unit 302 and a write drive unit 301.

The write drive unit 301 is configured to enhance the drive capability of the third write valid data WDATA3<127:0> and the first write parity bit data WPARITY1<7:0> and output a fourth write valid data WDATA4<127:0> and a second write parity bit data WPARITY2<7:0>, write the fourth write valid data WDATA4<127:0> into the main storage module, and write the second write parity bit data WPARITY2<7:0> into the parity bit storage module 220. The fourth write valid data WDATA4<127:0> is 16 8-bit binary numbers in parallel, and the second write parity bit data WPARITY2<7:0> is 1 8-bit binary number.

Specifically, the write drive unit 301 is configured to amplify the third write valid data WDATA3<127:0> and the first write parity bit data WPARITY1<7:0>, to enhance the drive capability of the third write valid data WDATA3<127:0> and the first write parity bit data WPARITY1<7:0>, to turn on or turn off a switching transistor of a corresponding storage unit. The amplified third write valid data WDATA3<127:0> is stored as the fourth write valid data WDATA4<127:0> into the main storage module, and the amplified first write parity bit data WPARITY1<7:0> is stored as the second write parity bit data WPARITY2<7:0> into the parity bit storage module 220.

The read drive unit 302 is configured to enhance the drive capability of a first read valid data RDATA1<127:0> and a first read parity bit data RPARITY1<7:0> output from the storage module 102, and output the second read valid data RDATA2<127:0> and the second read parity bit data RPARITY2<7:0>. The first read parity bit data RPARITY1<7:0> is an ECC checking data of the first read valid data RDATA1<127:0>. The first read valid data RDATA1<127:0> is 16 8-bit binary numbers in parallel, and the first read parity bit data RPARITY1<7:0> is 1 8-bit binary number.

Specifically, the read drive unit 302 is configured to amplify the first read valid data RDATA1<127:0> and the first read parity bit data RPARITY1<7:0>, to enhance the drive capability of the first read valid data RDATA1<127:0> and the first read parity bit data RPARITY1<7:0>, to turn on or turn off the switching transistor of the corresponding storage unit to ensure that the first read valid data RDATA1<127:0> and the first read parity bit data RPARITY1<7:0> can be read from the storage module 102. The amplified first read valid data RDATA2<127:0> as the second read valid data RDATA2<127:0> and the amplified first read parity bit data RPARITY1<7:0> as the second parity bit data RPARITY2<7:0> are transmitted to the read-write drive module 103 together.

In a specific example, when the memory performs a write operation through a data write channel in a normal operating state, the data pad 101 performs data interaction with the external controller to obtain the first write valid data WDATA1<127:0>, the first write valid data WDATA1<127:0> is the externally input data to be stored in the memory. The data pad 101 transmits the obtained first write valid data WDATA1<127:0> to the write data conversion unit 501, and the write data conversion unit 501 performs serial-to-parallel conversion on the first write valid data WDATA1<127:0> to convert the serial first write valid data WDATA1<127:0> into a plurality of second write valid data WDATA2<127:0> in parallel, and transmits the second write valid data WDATA2<127:0> to the write encoding unit 401. The write encoding unit 401 performs the ECC checking on the second write valid data WDATA2<127:0> to obtain the first write parity bit data WPARITY1<7:0> of the second write valid data WDATA2<127:0>, the second write valid data WDATA2<127:0> after the ECC checking as the third write valid data WDATA3<127:0>, is transmitted, together with the first write parity bit data WPARITY1<7:0>, to the write drive unit 301. The write drive unit 301 is configured to amplify the third write valid data WDATA3<127:0> and the first write parity bit data WPARITY1<7:0> to enhance the drive capability of the third write valid data WDATA3<127:0> and the first write parity bit data WPARITY1<7:0>. The amplified third write valid data WDATA3<127:0> is written into the main storage module as the fourth write valid data WDATA4<127:0>, and the amplified first write parity bit data WPARITY1<7:0> is written into the write parity bit storage module 220 as the second write parity bit data WPARITY2<7:0>.

In another specific example, when the memory performs a read operation through a data read channel in a normal operating state, the storage module 102 stores the first read valid data RDATA1<127:0> and the first read parity bit data RPARITY1<7:0>, the first read parity bit data RPARITY1<7:0> is the ECC checking data of the first read valid data RDATA1<127:0>. The read drive unit 302 is configured to amplify the first read valid data RDATA1<127:0> and the first read parity bit data RPARITY1<7:0> to enhance the drive capability of the first read valid data RDATA1<127:0> and the first read parity bit data RPARITY1<7:0> to ensure that the first read valid data RDATA1<127:0> and the first read parity data RPARITY1<7:0> can be read from the storage module 102. The amplified first read valid data RDATA1<127:0> as the second read valid data RDATA2<127:0>, and the amplified first read parity bit data RPARITY1<7:0> as the second read parity bit data RPARITY2<7:0> are transmitted to the read decoding unit 402 together. The reading decoding unit 402 performs the ECC checking and decoding on the second read valid data RDATA2<127:0> according to the second read parity bit data RPARITY2<7:0> to obtain the third read valid data RDATA3<127:0> decoded by the second read parity bit data RPARITY2<7:0>, and transmits the third read valid data RDATA3<127:0> to the read data conversion unit. The read data conversion unit performs parallel-to-serial conversion on the third read valid data RDATA3<127:0>, the plurality of third read valid data RDATA3<127:0> in parallel being converted into one fourth read valid data RDATA4<127:0> in serial, and transmits the fourth read valid data RDATA4<127:0> to the data pad 101. The data pad 101 performs data interaction with the external controller to output the read fourth read valid data RDATA4<127:0>.

In this embodiment, the memory also includes a compression read module 106 which is connected to both the read drive unit 302 and the read data conversion unit 502, and is configured to perform compression on the data information in the test mode to output the compressed data to the read data conversion unit 502.

The test mode is to test each storage unit in the storage module 102. It is determined whether there is a problematic storage unit in the storage module 102 by writing a high level to all storage units and determining according to data read from the storage module 102. Turning off the read decoding unit 402 is turning off the data read channel of the memory. Accordingly, the compression read module 106 is turned on so that the data can be checked by the compression read module 106. The purpose of writing a high level to the storage unit is to determine whether each storage unit in the storage module 102 can normally store high-level data.

Referring to FIG. 1, as for the write operation, when the storage module 102 is tested, the data processing module 104 converts the serial data on the data pad 101 into parallel data, and then distributes the parallel data to Data<127:0> and transmits it to the read-write drive module 103, and the corresponding ECC checking data is distributed to Dm<7:0> and written into the parity bit storage module 220 of the storage module 102. The read-write drive module 103 sequentially stores the received Data<127:0> into the main storage module 1 (201), the main storage module 2 (202) . . . the main storage module 15 (215), and the main storage module 16 (216), each main storage module storing an 8-bit parallel data, and writes Dm<7:0> into the parity bit storage module 220. As for the read operation, the data processing module 104 compresses the data to obtain the compressed data, checks whether the storage module 102 is in a normal operating state through the compressed data, and then after the parallel compressed data is converted from parallel data into serial data, it is output to the outside through the data pad 101. The read-write drive module 103 sequentially reads the data in each main storage module and the data in the parity bit storage module 220 into Data<127:0> and Dm<7:0>.

Specifically, referring to FIG. 2, When entering the test mode, the read decoding unit 402 is turned off and the compression read module 106 is turned on, a high level is written to each storage unit in the storage module 102, and the read drive unit 302 sends the second read valid data RDATA2<127:0> and the second read parity bit data RPARITY2<7:0> as test data TDATA<135:0> to the compression read module 106. The compression read module 106 compresses the received test data TDATA<135:0> to generate the compressed data, and outputs the compressed data to the data pad 101 through the read data conversion unit 502, so as to realize the output of the compressed data to the outside.

When no error is found in the decoding operation of error checking and correcting, the first write valid data WDATA1<127:0> is equal to the fourth read valid data RDATA4<127:0>; when a one-bit error is found in the decoding operation of error checking and correcting, the first write valid data WDATA1<127:0> is equal to the fourth read valid data RDATA4<127:0>; when a multi-bit error is found in the decoding operation of error checking and correcting, the first write valid data WDATA1<127:0> is not equal to the fourth read valid data RDATA4<127:0>.

Specifically, each storage unit in the storage module 102 is configured to store one-bit data, and a one-bit data error indicates that the storage module 102 has a problematic storage capacitor therein. The operation of error checking and correcting is configured to perform error checking on the read stored data, and when the error data is one-bit data, the operation of error checking and correcting is also configured to adjust the error data, that is, when no error is found in the decoding operation of error checking and correcting, the first write valid data WDATA1<127:0> is equal to the fourth read valid data RDATA4<127:0>; When a one-bit error is found in the decoding operation of error checking and correcting, the first write valid data WDATA1<127:0> is equal to the fourth read valid data RDATA4<127:0>; but when the error data is multi-bit data, the operation of error checking and correcting cannot adjust the error data, that is, when a multi-bit error is found in the decoding operation of error checking and correcting, the first write valid data WDATA1<127:0> is not equal to the fourth read valid data RDATA4<127:0>.

In this embodiment, the read-write drive module 103 performs data information interaction with the data processing module 104 through a valid data bus and a parity bit bus. The valid data bus is configured to transmit the valid data which includes the third write valid data WDATA3<127:0> and the second read valid data RDATA2<127:0>. The parity bit bus is configured to transmit the parity bit data which includes the first write parity bit data WPARITY1<7:0> and the second read parity bit data RPARITY2<7:0>.

In an example, the valid data bus has a width of 128 bits, and the parity bit bus has a width of 8 bits. That is, the valid data bus is configured to transmit 128-bit valid data which generates 8-bit parity bit data through the operation of error checking and correcting. The parity bit bus is configured to transmit the 8-bit parity bit data.

It is to be noted that, in other embodiments, the valid data bus is configured to transmit data that has any bit width. Based on 128 bits, each time the width of the valid data doubles, the bit width of the corresponding parity bit bus needs to be increased by one bit. The bit width of the valid data bus and the bit width of the parity bit bus can be specifically set according to the bit width of the specific transmission data.

In this embodiment, the read-write drive module 103 performs data information interaction with the compression read module 106 through the valid data bus and a mask data bus. The valid data bus is configured to transmit the second read valid data RDATA2<127:0>, and the mask data bus is configured to transmit the second read parity valid data RPARITY2<7:0>. The mask data bus is a bus used when the memory operates normally. The memory designed in this embodiment transmits part of data through the mask data bus in the test mode, thereby avoiding the introduction of an external bus and improving the stability of the test mode of the memory.

In an example, the valid data bus has a width of 128 bits, and the mask data bus has a width of 8 bits. The write drive unit 301 sends a 136-bit data combined by the 128-bit second read valid data and the 8-bit second read parity bit data to the compression read module 106. At this time, the 128-bit valid data bus and the 8-bit mask data bus are configured to transmit the 136-bit data together.

It is to be noted that, in other embodiments, the valid data bus is configured to transmit data that has any bit width. Based on 128 bits, each time the width of the valid data doubles, the bit width of the corresponding parity bit bus needs to be increased by one bit and the bit width of the corresponding mask data bus also needs to be increased by one bit. The bit width of the valid data bus and the bit width of the mask data bus can be specifically set according to the bit width of the specific transmission data.

Compared with the related art, when the test mode is in effect, the data read channel of the memory is turned off, the valid data and parity bit data stored in the memory are compressed by an additional compression unit to obtain the compressed data and to determine, through the processed data, whether an error has occurred in the main storage module and the parity bit storage module of the memory. Simultaneous testing on the stored data and the parity bit data increases the efficiency of the memory test; and the operation that the test results are obtained by compressing the data further improves the efficiency of the memory test.

It is worth mentioning that the modules involved in this embodiment are all logical modules. In practical applications, a logical unit may be a physical unit, a part of a physical unit, or a combination of a plurality of physical units. In addition, for highlighting innovative parts of the present disclosure, units related not so closely to the technical problem to be solved in the present disclosure are not introduced in the embodiment, but this does not mean that there are no other units in the embodiment.

The second embodiment of the present disclosure relates to a memory. Compared with the first embodiment, the second embodiment completes the writing of data into the storage module by newly adding a test case register which accelerates the speed of writing the test data into the memory and thus improves the test efficiency of the memory.

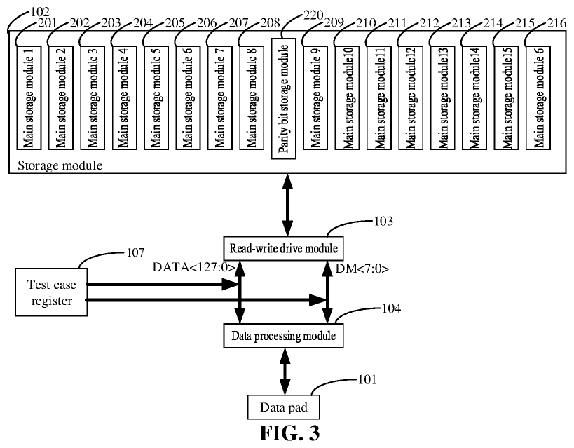

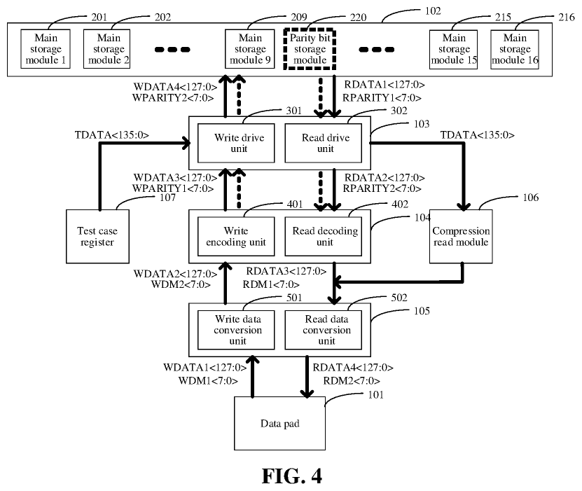

FIG. 3 and FIG. 4 are schematic structural diagrams of a memory provided by the embodiment of the present disclosure. The memory of this embodiment will be described in detail below. Parts the same as or corresponding to the above-mentioned embodiments will not be elaborated below.

Referring to FIG. 3 and FIG. 4, a memory also includes a test case register 107.

The test case register 107 is configured to store test data and connected to the write drive unit 301.

A test case refers to a description of a test task for a specific software product, reflecting a test plan, a method, a technology, and a strategy. Its content includes test objectives, test environment, input data, test steps, expected results, test scripts, etc., and finally a document is formed.

In this embodiment, the test case is configured to output test data to indicate each storage unit of the storage module to store a high level.

Before proceeding to the test mode, the test case is stored in the test case register 107; when entering the test mode, the write encoding unit is turned off, the test case register 107 is turned on to output the test data which is configured to test the main storage module and the parity bit storage module 220.

Referring to FIG. 1, as for the write operation, when the storage module 102 is tested, the data processing module 104 turns off the data write channel to the read-write drive module 103. The test case register 107 outputs the test data, and the test data includes Data<127:0> and Dm<7:0>. The read-write drive module 103 sequentially stores the received Data<127:0> into the main storage module 1 (201), the main storage module 2 (202) . . . the main storage module 15 (215), and the main storage module 16 (216), each main storage module storing an 8-bit parallel data, and writes Dm<7:0> into the parity bit storage module 220. As for the read operation, the data processing module 104 compresses the data to obtain the compressed data, checks whether the storage module 102 is in a normal operating state through the compressed data, and then converts the parallel compressed data from parallel data into serial data which is output to the outside through the data pad 101. The read-write drive module 103 sequentially reads the data in each main storage module and the data in the parity bit storage module 220 into Data<127:0> and Dm<7:0>.

Specifically, referring to FIG. 2, before proceeding to the test mode, the test case is stored in the test case register 107. The test case is configured to output the test data to instruct to store a high level into the main storage module and the parity bit storage module 220. The purpose of writing a high level into the storage unit is to determine whether each storage unit in the storage module can normally store high-level data. When entering the test mode, the write encoding unit is turned off, that is the data write channel of the memory is turned off, and the test case register 107 is turned on. The test case register 107 outputs pre-stored test data and completes the writing of data into the main storage module and the parity bit storage module 220 through the test data, thereby realizing the test on the main storage module and the parity bit storage module 220.

In this embodiment of the present disclosure, the test case register 107 performs data information interaction with the read-write drive module through the valid data bus and the parity bit bus.

In an example, the valid data bus has a width of 128 bits, and the parity bit bus has a width of 8 bits. That is, the valid data bus is configured to transmit 128-bit valid data which generates 8-bit parity bit data through the operation of error checking and correcting. The parity bit bus is configured to transmit the 8-bit parity bit data.

Specifically, the valid data and the parity bit data are stored through the test case. When entering the test mode, the test case register 107 inputs, based on the test case, 128 as the valid data through the valid data bus into the storage module, and inputs 8 as the parity bit data through the parity bit bus into the storage module. The valid data memory is in the main storage module of the storage module. The 8 bit parity bit data is stored in the parity bit storage module 220 of the storage module.

It is to be noted that, in other embodiments, the valid data bus is configured to transmit data that has any bit width. Based on 128 bits, each time the width of the valid data doubles, the bit width of the corresponding parity bit bus needs to be increased by one bit. The bit width of the valid data bus and the bit width of the parity bit bus can be specifically set according to the bit width of the specific transmission data.

Compared with the related art, when the test mode is in effect, the data read channel of the memory is turned off, the valid data and the parity bit data stored in the memory are compressed by an additional compression unit to obtain the compressed data and to determine, through the processed data, whether an error has occurred in the main storage module and the parity bit storage module of the memory. Simultaneous testing on the stored data and the parity bit data increases the efficiency of the memory test; and the operation that the test results are obtained by compressing the data further improves the efficiency of the memory test. Further, the test data is stored through the test case register, when the memory is tested, the test data output from the test case register being directly written into the main storage module and the parity bit storage module in the memory speeds up the test data writing speed and therefore increases the test efficiency of the memory.

It is worth mentioning that the modules involved in this embodiment are all logical modules. In practical applications, a logical unit may be a physical unit, a part of a physical unit, or a combination of a plurality of physical units. In addition, for highlighting innovative parts of the present disclosure, units related not so closely to the technical problem to be solved in the present disclosure are not introduced in the embodiment, but this does not mean that there are no other units in the embodiment.

A third embodiment of the present disclosure provides a method for testing a memory.

The method for testing a memory provided in the embodiment will be described below in detail in combination with the drawing. Parts the same as or corresponding to the first and second embodiments will not be elaborated below.

The method for testing a memory, which is applied to the memory in the first embodiment, includes the following operations. Test data is input into the memory based on the data pad. The test data is written into the main storage module and the parity bit storage module. The test data stored in the main storage module and the parity bit storage module is read through the compression read module and the compressed data is output. It is determined based on the compressed data whether the storage module is in a normal operating state.

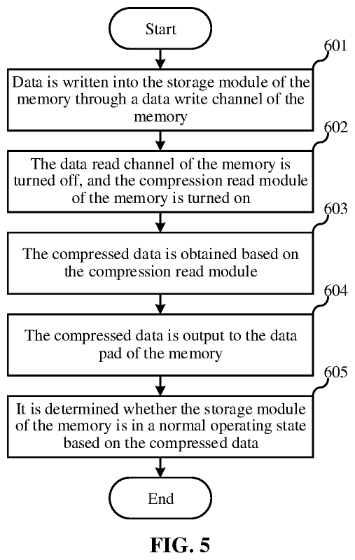

Referring to FIG. 5, the method for testing a memory includes the following operations.

At S601, data is written into the storage module of the memory through a data write channel of the memory.

Specifically, referring to FIG. 2, when a writing operation is carried out through the data write channel, the data pad 101 performs data interaction with an external controller to obtain a first write valid data WDATA1<127:0>. The first write valid data WDATA1<127:0> is externally input data which is to be stored in the memory.

The data pad 101 transmits the obtained first write valid data WDATA1<127:0> to a write data conversion unit 501. The write data conversion unit 501 performs serial-to-parallel conversion on the first write valid data WDATA1<127:0> to convert the serial first write valid data WDATA1<127:0> into a plurality of second write valid data WDATA2<127:0> in parallel, and transmits the second write valid data WDATA2<127:0> to a write encoding unit 401

The write encoding unit 401 performs an ECC checking on the second write valid data <127:0> to obtain a first write parity bit data WPARITY1<7:0> of the second write valid data WDATA2<127:0>. The second write valid data WDATA2<127:0>, after the ECC checking, is used as a third write valid data WDATA3<127:0> which is transmitted, together with the first write parity bit data WPARITY1<7:0>, to the write drive unit 301.

The write drive unit 301 is configured to amplify the third write valid data WDATA3<127:0> and the first write parity bit data, to enhance the drive capability of the third write valid data WDATA3<127:0> and the first write parity bit data WPARITY1<7:0>. The amplified third write valid data WDATA3<127:0> is written as a fourth write valid data WDATA4<127:0> into the main storage module, and the amplified first write parity bit data WPARITY1<7:0> is stored as a second write parity bit data WPARITY2<7:0> into the parity bit storage module.

Referring to FIG. 5 again, at S602, the data read channel of the memory is turned off, and the compression read module of the memory is turned on. At S603, the compressed data is obtained based on the compression read module. At S604, the compressed data is output to the data pad of the memory.

Referring to FIG. 2, specifically, the read drive unit 302 sends the second read valid data RDATA2<127:0> and the second read parity bit data RPARITY2<7:0> as the test data TDATA<135:0> to the compression read module 106, and the compression read module 106 compresses the received test data TDATA<135:0> to generate the compressed data, and outputs the compressed data to the data pad 101 through the read data conversion unit 502, so as to realize the output of the compressed data to the outside.

Referring to FIG. 5 again, at S605, it is determined whether the storage module of the memory is in a normal operating state based on the compressed data.

Referring to FIG. 2, specifically, each storage unit in the storage module 102 is configured to store one bit of high-level data, and a one-bit data error indicates that the storage module 102 has a problematic storage capacitor therein. The operation of error checking and correcting is configured to perform error checking on the read stored data, and when the error data is one-bit data, the operation of error checking and correcting is also configured to adjust the error data, that is, when no error is found in the decoding operation of error checking and correcting, the first write valid data WDATA1<127:0> is equal to the fourth read valid data RDATA4<127:0>; when a one-bit error is found in the decoding operation of error checking and correcting, the first write valid data WDATA1<127:0> is equal to the fourth read valid data RDATA4<127:0>; but when the error data is multi-bit data, the operation of error checking and correcting cannot adjust the error data, that is, when a multi-bit error is found in the decoding operation of error checking and correcting, the first write valid data WDATA1<127:0> is not equal to the fourth read valid data RDATA4<127:0>.

The method for testing a memory, which applies to the memory of the second embodiment, includes the following operations. Test data is stored into the test case register. The test data output from the test case register is written into the main storage module and the parity bit storage module. The test data stored in the main storage module and the parity bit storage module is read through the compression read module and compressed data is output. It is determined based on the compressed data whether the storage module is in a normal operating state.

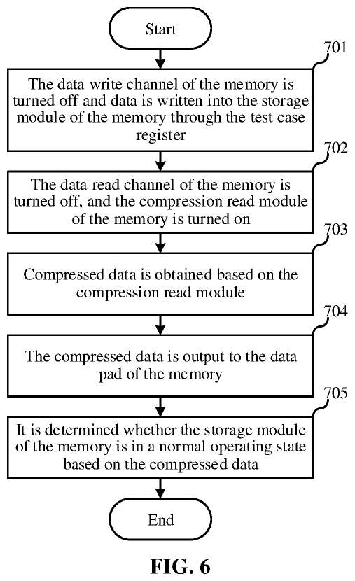

Referring to FIG. 6, the method for testing a memory includes the following operations.

At S701, the data write channel of the memory is turned off and data is written into the storage module of the memory through the test case register.

Referring to FIG. 4, when the test data is stored into the test case register 107 of the memory, the test data is configured to test the storage module 102 of the memory, the test case register 107 is turned on, and the test case register 107 outputs the test data to the storage module 102.

Specifically, before proceeding to the test mode, the test data is stored in the test case register 107. The test data is configured to instruct to store a high level into the main storage module and the parity bit storage module 220. The purpose of writing a high level into the main storage module and the parity bit storage module 220 is to determine whether the storage module 102 can normally store high-level data. When entering the test mode, the write encoding unit 401 is turned off, that is the data write channel of the memory is turned off and the test case register 107 is turned on. The test case register 107 outputs pre-stored test data and completes the writing of data into the main storage module and the parity bit storage module 220 through the test data, thereby realizing the test on the storage module 102.

Referring to FIG. 6 again, at S702, the data read channel of the memory is turned off, and the compression read module of the memory is turned on. At S703, compressed data is obtained based on the compression read module. At S704, the compressed data is output to the data pad of the memory.

Referring to FIG. 5, specifically, the read drive unit 302 sends the second read valid data RDATA2<127:0> and the second read parity bit data RPARITY2<7:0> as test data TDATA<135:0> to the compression read module 106, and the compression read module 106 compresses the received test data TDATA<135:0> to generate compressed data, and outputs the compressed data to the data pad 101 through the read data conversion unit 502, so as to realize the output of the compressed data to the outside.

Referring to FIG. 6 again, at S705, it is determined whether the storage module of the memory is in a normal operating state based on the compressed data.

Referring to FIG. 5, specifically, each storage unit in the storage module 102 is configured to store one bit of high-level data, and a one-bit data error indicates that the storage module 102 has a problematic storage capacitor therein. The operation of error checking and correcting is configured to perform error checking on the read stored data, and when the error data is one-bit data, the operation of error checking and correcting is also configured to adjust the error data, that is, when no error is found in the decoding operation of error checking and correcting, the first write valid data WDATA1<127:0> is equal to the fourth read valid data RDATA4<127:0>; when a one-bit error is found in the decoding operation of error checking and correcting, the first write valid data WDATA1<127:0> is equal to the fourth read valid data RDATA4<127:0>; but when the error data is multi-bit data, the operation of error checking and correcting cannot adjust the error data, that is, when a multi-bit error is found in the decoding operation of error checking and correcting, the first write valid data WDATA1<127:0> is not equal to the fourth read valid data RDATA4<127:0>.

Compared with the related art,

when the test mode is in effect, a data read channel of the memory is turned off, the valid data and parity bit data stored in the memory are compressed by an additional compression unit to obtain the compressed data and to determine, through the processed data, whether an error has occurred in the main storage module and the parity bit storage module of the memory. Simultaneous testing on the stored data and the parity bit data increases the efficiency of the memory test; and the operation that the test results are obtained by compressing the data further improves the efficiency of the memory test. Further, the test data is stored through the test case register 107, when the memory is tested, the test data output from the test case register 107 being written directly into the main storage module and the parity bit storage module in the memory accelerates the test data writing speed and therefore increases the test efficiency of the memory.

The above steps are divided only for clear description. During implementation, the operations may be combined into one operation, or some operations may be split into multiple operations, and any solution including the same logical relationship falls within the scope of protection of the present disclosure. Adding insignificant modifications to the process or introducing insignificant designs without changing the core design of the flow falls within the scope of protection of the present disclosure.

Since the first and second embodiments correspond to the present embodiment, so that the present embodiment can be matched with the first and second embodiments for implementation. The related technical details mentioned in the first and second embodiments are still effective in the present embodiment, and the technical effects that may be achieved in the first and second embodiments may also be achieved in the present embodiment. For reducing repetitions, elaborations are omitted herein. Correspondingly, related technical details mentioned in the present embodiment may also be applied to the first and second embodiments.

It should be understood that, in the embodiments of the present disclosure, the storage module may be implemented by using a storage circuit, the main storage module may be implemented by using a main storage circuit, the parity bit storage module may be implemented by using a parity bit storage circuit, the read-write drive module may be implemented by using a read-write drive circuit, the data processing module may be implemented by using a data processing circuit, the write data conversion module may be implemented by using a write data conversion circuit, the read data conversion module may be implemented by using a read data conversion circuit, the write encoding module may be implemented by using a write encoding circuit, the read decoding module may be implemented by using a read decoding circuit, the write drive unit may be implemented by using a write drive circuit, the read drive module may be implemented by using a read drive circuit, and the compression read module may be implemented by using a compression read circuit, etc.

Those of ordinary skill in the art can understand that each embodiment is a specific embodiment implementing the present disclosure, and in practical applications, various variations about the form and details can be made thereto without departing from the spirit and scope of the present disclosure.

1. A memory, comprising:
a storage circuit, configured to store data information, wherein the storage circuit comprises main storage circuits and a parity bit storage circuit, the main storage circuit is configured to store valid data, and the parity bit storage circuit is configured to store parity bit data;
a read-write drive circuit, connected to the storage circuit and configured to read the data information from the storage circuit, or write the data information into the storage circuit; and
a data processing circuit, connected to the read-write drive circuit and configured to perform a decoding operation of error checking and correcting on the data information output from the read-write drive circuit, or perform an encoding operation of error checking and correcting on the data information input into the read-write drive circuit.

2. The memory of claim 1, further comprising:
a data pad, configured to exchange a first write valid data and a fourth read valid data with an external controller;
a write data conversion circuit, connected to both the data pad and the data processing circuit and configured to perform serial-to-parallel conversion on the first write valid data and output a second write valid data to the data processing circuit; and
a read data conversion circuit, connected to both the data pad and the data processing circuit and configured to perform parallel-to-serial conversion on a third read valid data output from the data processing circuit and output the fourth read valid data to the data pad.

3. The memory of claim 2, wherein the data processing circuit comprises:
a write encoding circuit, connected to both the read-write drive circuit and the write data conversion circuit and configured to perform the encoding operation of error checking and correcting on the second write valid data, wherein the write encoding circuit is configured to output a third write valid data and a first write parity bit data; and
a read decoding circuit, connected to both the read-write drive circuit and the read data conversion circuit, and configured to perform the decoding operation of error checking and correcting on a second read valid data and a second read parity bit data output from the read-write drive circuit, wherein the read decoding circuit is configured to output the third read valid data.

4. The memory of claim 3, wherein the read-write drive circuit comprises:
a write drive circuit, configured to enhance a drive capability of the third write valid data and the first write parity bit data, output a fourth write valid data and a second write parity bit data, write the fourth write valid data into the main storage circuit, and write the second write parity bit data into the parity bit storage circuit; and
a read drive circuit, configured to enhance a drive capability of a first read valid data and a first read parity bit data, and output the second read valid data and the second read parity bit data.

5. The memory of claim 4, further comprising:
a compression read circuit, connected to both the read drive circuit and the read data conversion circuit, and configured to perform compression on the data information in a test mode to output compressed data to the read data conversion circuit.

6. The memory of claim 5, wherein when no error is found in the decoding operation of error checking and correcting, the first write valid data is equal to the fourth read valid data; when a one-bit error is found in the decoding operation of error checking and correcting, the first write valid data is equal to the fourth read valid data; when a multi-bit error is found in the decoding operation of error checking and correcting, the first write valid data is not equal to the fourth read valid data.

7. The memory of claim 5, wherein the memory is configured to, when entering the test mode, turn off the read decoding circuit and turn on the compression read circuit, the read drive circuit is configured to send the second read valid data and the second read parity bit data to the compression read circuit, and the compressed data is output to the data pad through the read data conversion circuit.

8. The memory of claim 5, wherein the read-write drive circuit is configured to perform interaction of the data information with the data processing circuit through a valid data bus and a parity bit bus, and the read-write drive circuit is configured to perform interaction of the data information with the compression read circuit through the valid data bus and a mask data bus.

9. The memory of claim 8, wherein the valid data bus has a width of 128 bits, the parity bit bus has a width of 8 bits, and the mask data bus has a width of 8 bits.

10. The memory of claim 5, further comprising: a test case register configured to store test data and connected to the write drive circuit.

11. The memory of claim 10, wherein the test case register is configured to perform interaction of the data information with the read-write drive circuit through a valid data bus and a parity bit bus.

12. The memory of claim 11, wherein the valid data bus has a width of 128 bits, and the parity bit bus has a width of 8 bits.

13. The memory of claim 10, wherein the memory is configured to, before entering the test mode, store the test data in the test case register; when entering the test mode, turn off the write encoding circuit and turn on the test case register, which is configured to output test data to test the main storage circuit and the parity bit storage circuit.

14. A method for testing a memory, applied to the memory of claim 5, the method comprising:
outputting test data into the memory based on the data pad;
writing the test data into the main storage circuit and the parity bit storage circuit;
reading the test data stored in the main storage circuit and the parity bit storage circuit through the compression read circuit and outputting the compressed data; and
determining whether the storage circuit is in a normal operating state based on the compressed data.

15. A method for testing a memory, applied to the memory of claim 10, the method comprising:
storing the test data into the test case register;
writing the test data output from the test case register into the main storage circuit and the parity bit storage circuit;
reading the test data stored in the main storage circuit and the parity bit storage circuit through the compression read circuit and outputting the compressed data; and
determining whether the storage circuit is in a normal operating state based on the compressed data.
